(19) United States
(12) Patent Application Publication
(10) Pub. No.: US 2012/0001241 A1
(43) Pub. Date: Jan. 5, 2012

(54) CMOS Image Sensor Including PNP Triple Layer And Method Of Fabricating The CMOS Image Sensor

(75) Inventor: Won-je Park, Yongin-si (KR)

(73) Assignee: SAMSUNG ELECTRONICS CO., LTD., Suwon-si (KR)

(21) Appl. No.: 13/160,915

(22) Filed: Jun. 15, 2011

(30) Foreign Application Priority Data
Jun. 30, 2010 (KR) 10-2010-0063153

(51) Int. Cl. H01L 27/146

(52) U.S. Cl. 257/292; 257/E27.133

(57) ABSTRACT

A CMOS image sensor (CIS) for sensing visible light and infrared (IR) light, capable of effectively preventing increase in electrical crosstalk that is caused when photodiodes are formed deeply and the thickness of an epitaxial layer is increased due to deep permeation of IR light, and a method of fabricating the CIS. The CIS includes a substrate; the PNP triple layer including a P-type lower layer, an N-type intermediate layer, and a P-type upper layer that are sequentially stacked on the substrate; a plurality of photodiodes formed in the P-type upper layer and isolated from each other by isolation regions; a wiring layer formed on the P-type upper layer and the plurality of photodiodes and including a plurality of wirings; and a plurality of lenses for focusing light to transfer the light to the photodiodes.

### CROSS-REFERENCE TO RELATED APPLICATIONS

This application claims the benefit of Korean Patent Application No. 10-2010-0063153, filed on Jun. 30, 2010, in the Korean Intellectual Property Office (KIPO), the entire contents of which are incorporated herein in its entirety by reference.

### BACKGROUND

Example embodiments relate to a CMOS image sensor (CIS), and more particularly, to a CIS for sensing visible light and infrared (IR) light, and a method of fabricating the CIS.

Due to current development of information communication industries and digitalization of electronic devices, performance-improved image sensors are used in various devices such as digital cameras, camcorders, mobile phones, personal communication systems (PCSs), game devices, security cameras, and medical micro cameras. As semiconductor products are becoming more highly integrated, a unit cell area is becoming smaller and a line width in and a distance between patterns is also becoming smaller. However, excellent electrical characteristics and low power consumption characteristics are still required in devices.

In general, image sensors are semiconductor devices for converting an optical image into an electrical signal. Examples of image sensors include a charge coupled device (CCD) in which individual metal-oxide-silicon (MOS) capacitors are arranged relatively close to each other and charge carriers are stored in and then are transferred from a capacitor, and a CIS that employs a switching method of sequentially sensing outputs by using a number of MOS transistors formed to correspond to the number of pixels of the CIS based on a CMOS technology in which a control circuit and a signal processing circuit in a peripheral circuit are founed.

Also, another example of image sensors is a thermal IR image sensor including a lens for concentrating thermal IR light irradiated from an object having a constant temperature, thermal IR sensors for sensing thermal IR light, and a readout chip for extracting signals output from the thermal IR sensors. Here, the thermal IR sensors may be divided into a semiconductor type using a semiconductor and a thermal type using a thermal effect.

The semiconductor type thermal IR sensors sense electron-holes excited due to thermal IR light when thermal IR light is incident thereon, by using a material having a low band gap, and thus the semiconductor type thermal IR sensors have a high sensitivity. In the semiconductor type thermal IR sensors, a readout chip for processing signals requires a high amplification rate and a complicated denoising process. Thus, the semiconductor type thermal IR sensors are generally fabricated by using a CMOS process.

Meanwhile, the thermal type thermal IR sensors measure a thermal image by allowing thermal IR light concentrated by a lens to be absorbed by a thermal IR absorber and thus increasing the temperature of the thermal IR absorber. The thermal type thermal IR sensor may use a method using a material in which a phase change occurs due to slight temperature changes, a method using characteristics of a ferroelectric material that varies according to temperature, or a method using thermoelectromotive force generated when temperature increases.

### SUMMARY

Example embodiments provide a CMOS image sensor (CIS) for sensing visible light and infrared (IR) light, capable of effectively preventing increase in electrical crosstalk that is caused when photodiodes are formed deeply and the thickness of an epitaxial layer is increased due to deep permeation of IR light, and a method of fabricating the CIS.

According to an aspect of example embodiments, there is provided a CMOS image sensor (CIS) including a PNP triple layer, the CIS including a substrate; the PNP triple layer including a P-type lower layer, an N-type intermediate layer, and a P-type upper layer that are sequentially stacked on the substrate; a plurality of photodiodes formed in the P-type upper layer and isolated from each other by isolation regions; a wiring layer formed on the P-type upper layer and the plurality of photodiodes and including a plurality of wirings; and a plurality of lenses for focusing light to transfer the light to the photodiodes.

The substrate may be a heavily-doped P-type (P++) substrate, and the P-type lower layer, the N-type intermediate layer, and the P-type upper layer may be epitaxial layers, or, the P-type lower layer and the P-type upper layer may be epitaxial layers, and the N-type intermediate layer may be an implantation layer.

The substrate may be divided into a pixel region and a peripheral circuit region, and the N-type intermediate layer may be formed in both the pixel region and the peripheral circuit region, or in only the pixel region. The N-type intermediate layer may be maintained in a floating state in which a voltage is not applied. Meanwhile, a ground bias voltage may be applied to the substrate, the P-type lower layer, and the P-type upper layer through a deep P-type well formed on the substrate outside the pixel region.

The plurality of photodiodes may include visible light photodiodes for sensing visible light and infrared (IR) photodiodes for sensing IR light. Each of the plurality of photodiodes may include a lower N-type photodiode (NPD) region and an upper P-type photodiode (PPD) region, and each of the IR photodiodes may further include a deep NPD region under the NPD region. The deep NPD region may extend from the P-type upper layer to the N-type intermediate layer or extend from the P-type upper layer to the P-type lower layer through the N-type intermediate layer.

According to another aspect of example embodiments, there is provided a CMOS image sensor (CIS) including a PNP triple layer, the CIS including a substrate including a pixel region and a peripheral circuit region; the PNP triple layer including a P-type lower layer, an N-type intermediate layer, and a P-type upper layer that are sequentially stacked on the substrate in the pixel region; a plurality of photodiodes formed in the P-type upper layer in the pixel region and isolated from each other by isolation regions; a wiring layer formed on the P-type upper layer and the photodiodes and including a plurality of wirings; and a plurality of lenses for focusing light to transfer the light to the photodiodes.

The PNP triple layer may be formed in the peripheral circuit region, a plurality of P-type wells and N-type wells for forming CMOS circuits may be alternately formed in the P-type upper layer in the peripheral circuit region, a deep P-type well may be formed under a P-type well-N-type well-P-type well structure, and a deep N-type well may be formed under an N-type well-P-type well-N-type well structure, and the deep P-type well may contact the P-type wells of the P-type well-N-type well-P-type well structure, and extend from the P-type upper layer to the P-type lower layer through the N-type intermediate layer. Meanwhile, a ground bias voltage may be applied to the substrate through one P-type well, the deep P-type well, and the P-type lower layer. Also, a P-type doping region may be formed under the deep N-type well.

According to another aspect of example embodiments, there is provided a method of fabricating a CMOS image sensor (CIS) including a PNP triple layer, the method including preparing a substrate including a pixel region and a peripheral circuit region; forming the PNP triple layer including a P-type lower layer, an N-type intermediate layer, and a P-type upper layer that are sequentially stacked on the substrate; forming trenches in the PNP triple layer to form an isolation layer; forming a plurality of P-type wells and N-type wells for forming CMOS circuits in the peripheral circuit region; forming in the pixel region a plurality of photodiodes isolated from each other by the isolation layer; and forming on the photodiodes a wiring layer including a plurality of metal wirings.

The forming of the PNP triple layer may include forming the P-type lower layer by growing a P-type epitaxial layer on the substrate; forming the N-type intermediate layer by growing an N-type epitaxial layer on the P-type lower layer; and forming the P-type upper layer by growing a P-type epitaxial layer on the N-type intermediate layer. Also, the forming of the PNP triple layer may include growing on the substrate a P-type epitaxial layer having a predetermined thickness; and forming the N-type intermediate layer by performing ion implantation in the middle of the P-type epitaxial layer, and a portion of the P-type epitaxial layer under the N-type intermediate layer may be the P-type lower layer and a portion of the P-type epitaxial layer on the N-type intermediate layer may be the P-type upper layer. Meanwhile, the forming of the N-type intermediate layer may include performing the ion implantation on only the pixel region, and a P-type monolayer may be formed on the substrate in the peripheral circuit region by the growing of the P-type epitaxial layer.

Meanwhile, if the N-type intermediate layer is formed in both the pixel region and the peripheral circuit region, the forming of the P-type wells and the N-type wells may include forming a deep P-type well under a P-type well-N-type well-P-type well structure and a deep N-type well under an N-type well-P-type well-N-type well structure, and the deep P-type well may contact the P-type wells of the P-type well-N-type well-P-type well structure, and extend from the P-type upper layer to the P-type lower layer through the N-type intermediate layer. Also, the forming of the P-type wells and the N-type wells may include forming a P-type doping region under the deep N-type well.

The photodiodes may include visible light photodiodes for sensing visible light and infrared (IR) photodiodes for sensing IR light, and each of the photodiodes may be formed by forming an N-type photodiode (NPD) region and a P-type photodiode (PPD) region in the P-type upper layer by performing ion implantation. Also, each of the IR photodiodes may be formed by forming a deep NPD region under the NPD region. The deep NPD region may extend from the P-type upper layer to the N-type intermediate layer or extend from the P-type upper layer to the P-type lower layer through the N-type intermediate layer.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a cross-sectional view of a CMOS image sensor (CIS) including a PNP triple layer, according to an example embodiment;

FIG. 2 is a cross-sectional view of a CIS including a PNP triple layer, according to another example embodiment;

FIG. 3 is a cross-sectional view of a CIS including a PNP triple layer, according to another example embodiment;

FIG. 4 is a schematic view for describing operation of the CIS illustrated in FIG. 1, according to an example embodiment;

FIGS. 5 through 10 are cross-sectional views for describing a method of fabricating the CIS illustrated in FIG. 1, according to an example embodiment;

FIGS. 11 and 12 are cross-sectional views for describing a process of forming the PNP triple layer of the CIS illustrated in FIG. 1, according to another example embodiment;

FIG. 13 is a cross-sectional view for describing a process of forming the PNP triple layer of the CIS illustrated in FIG. 1, according to another example embodiment; and

FIG. 14 is a block diagram of an electric and electronic system including a CIS, according to an example embodiment.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

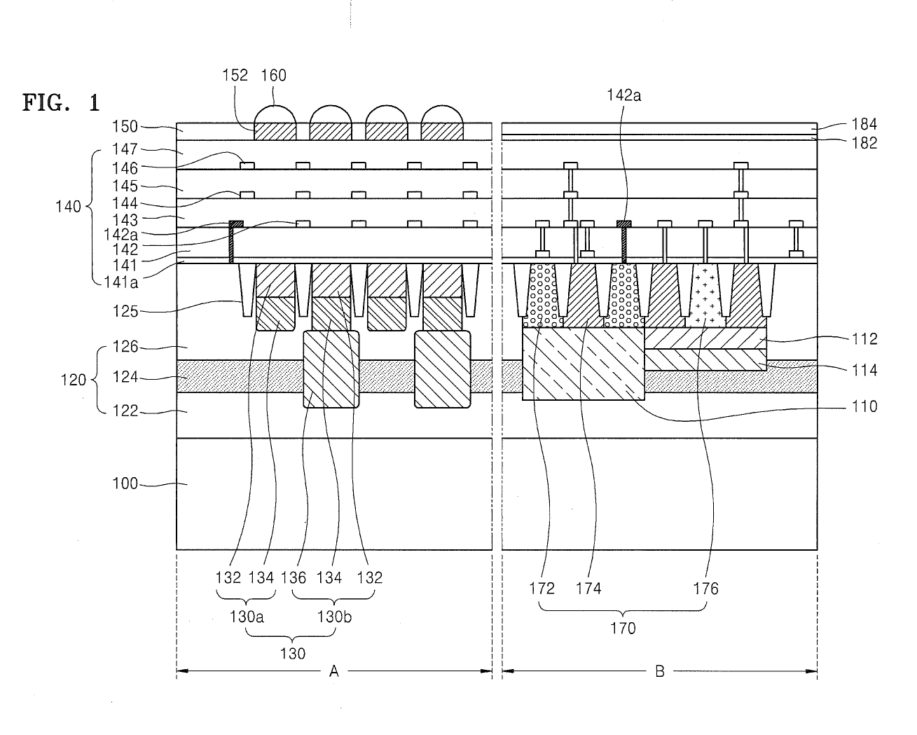

FIG. 1 is a cross-sectional view of a CMOS image sensor (CIS) including a PNP triple layer 120, according to an example embodiment.

Referring to FIG. 1, the CIS according to the current embodiment may include a substrate 100, the PNP triple layer 120, a plurality of photodiodes 130, a wiring layer 140, a filter layer 150, and a plurality of lenses 160.

The substrate 100 may be formed by using an epitaxial wafer. An epitaxial wafer refers to a wafer formed by growing a crystalline material on a monocrystalline silicon substrate. However, the substrate 100 is not limited to an epitaxial wafer and any of various wafers such as a polished wafer, an annealed wafer, and a silicon on insulator (SOI) wafer may also be used as the substrate 100.

The substrate 100 may be a heavily-doped P-type (P++) substrate formed by growing an epitaxial layer originally heavily-doped with P-type ions or by injecting ions into an epitaxial wafer such that the substrate is heavily-doped with P-type ions.

Meanwhile, the substrate 100 may be divided into a pixel region A, i.e., an active pixel sensor (APS) region, in which the photodiodes 130 are formed, and a peripheral circuit region B for processing signals.

The PNP triple layer 120 is formed on the substrate 100 and includes a P-type lower layer 122, an N-type intermediate layer 124, and a P-type upper layer 126. Like the substrate 100, each layer of the PNP triple layer 120 may be formed by growing a corresponding doping-type epitaxial layer or by injecting corresponding doping-type ions into an epitaxial layer. Meanwhile, the PNP triple layer 120 may be formed in both the pixel region A and the peripheral circuit region B. Also, the P-type lower layer 122 and the P-type upper layer 126 of the PNP triple layer 120 may function as depletion layers and thus may have relatively low doping concentrations. Meanwhile, the N-type intermediate layer 124 may have a doping concentration similar to or slightly greater than that of the P-type lower layer 122 or that of the P-type upper layer 126.

Meanwhile, isolation regions 125 such as shallow trench isolations (STIs), the photodiodes 130, and a well region 170 for CMOS circuits may be formed in the P-type upper layer 126 of the PNP triple layer 120. For example, in the P-type upper layer 126, the photodiodes 130 may be formed in the pixel region A, the well region 170 for CMOS circuits may be formed in the peripheral circuit region B, and the isolation regions 125 may be formed at appropriate positions with an appropriate thickness to electrically isolate elements from each other.

The photodiodes 130 may include visible light photodiodes 130a for sensing visible light and infrared (IR) photodiodes 130b for sensing IR light.

Each of the visible light photodiodes 130a may include an upper P-type photodiode (PPD) region 132, i.e., a P-type impurity region, and a lower N-type photodiode (NPD) region 134, i.e., an N-type impurity region. The PPD region 132 and the NPD region 134 may have intermediate doping concentrations, and the doping concentration of the PPD region 132 may be greater than that of the NPD region 134.

Since visible light permeates shallowly, the visible light photodiodes 130a may be formed shallowly in the P-type upper layer 126, and the P-type upper layer 126 may sufficiently function as a depletion layer for forming electron-hole pairs.

Meanwhile, in addition to the PPD region 132 and the NPD region 134, each of the IR photodiodes 130b may further include a deep NPD region 136 under the NPD region 134. The deep NPD region 136 may have a doping concentration less than that of the NPD region 134. For example, the doping concentration of the deep NPD region 136 may be less than that of the NPD region 134. For example, the doping concentration of the deep NPD region 136 may be about 1/10 of that of the NPD region 134.

Since IR light permeates deeply, a depletion layer for forming electron-hole pairs may extend to the P-type lower layer 122, and thus the IR photodiodes 130b have to be deeply formed to efficiently sense IR light. The deep NPD region 136 may increase the efficiency of IR sensing by receiving carriers, e.g., electrons, generated from the P-type lower layer 122 and the substrate 100 in the IR photodiodes 130b.

Meanwhile, in IR sensing, since electron-hole pairs are generated in a relatively deep place, such as the substrate 100, a phenomenon in which some of the generated carriers, i.e., minority carriers, move to photodiodes of a neighboring pixel, i.e., crosstalk, increases. In order to prevent crosstalk, conventionally, a deep P-type well may be formed. However, this method prevents extension of a depletion layer for visible light photodiodes and thus reduces the sensitivity of the visible light photodiodes, and does not sufficiently block minority carriers. Alternatively, a structure of an N-type substrate/an N-type epitaxial layer, or an N-type substrate/a P-type epitaxial layer may be used. However, this method seriously reduces the sensitivity of IR sensing and thus is not appropriate for a CIS for performing IR sensing.

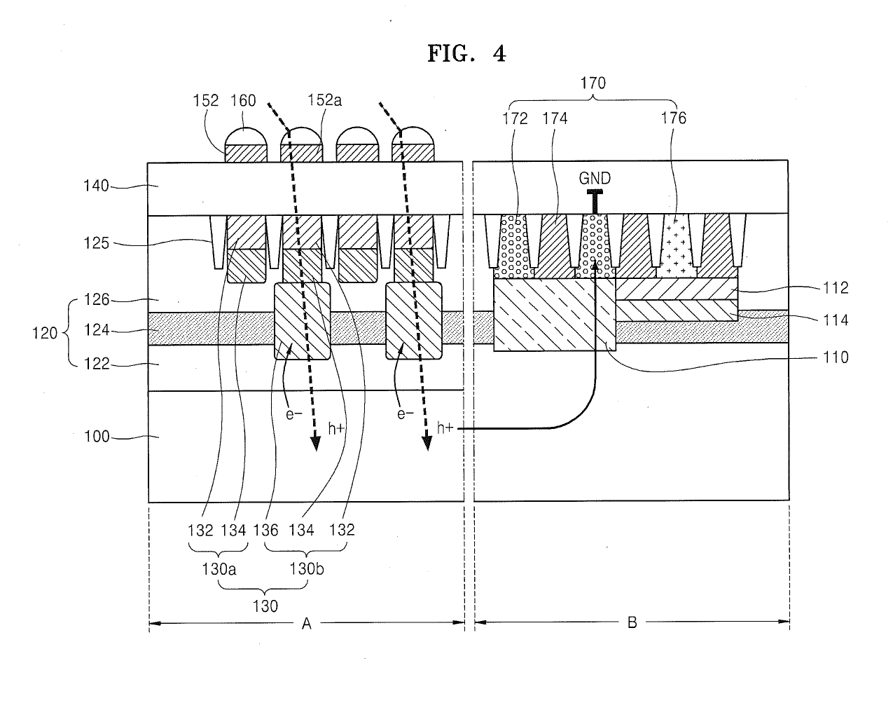

In the current embodiment, as the PNP triple layer 120 is formed on the substrate 100, carriers, i.e., electrons, generated from a lower side of the N-type intermediate layer 124 move only to the IR photodiode 130b of a corresponding pixel and not to the visible light photodiode 130a of another pixel, because, although the electrons may be diffused toward a neighboring pixel, the electrons are drained by the N-type intermediate layer 124 and are drawn toward the deep NPD region 136 of the IR photodiode 130b of the corresponding pixel. Meanwhile, holes flow to ground through the heavily-doped P-type (P++) substrate 100 and a deep P-type well 110 for applying a ground bias voltage to the substrate 100. The flow of the holes will be described in detail later with reference to FIG. 4.

In the P-type upper layer 126 in the peripheral circuit region B, a plurality of P-type wells 172 and N-type wells 174 may be formed to form CMOS circuits. Meanwhile, since the N-type intermediate layer 124 is also formed in the peripheral circuit region B, the deep P-type well 110 may be formed under a P-type well-N-type well-P-type well structure around one of the N-type wells 174 to form a CMOS circuit, and a ground electrode 142a may be formed on one of the P-type wells 172 thereof. Here, the deep P-type well 110 may have an intermediate doping concentration, for example, a doping concentration of 10⁻¹⁴/cm³.

Also, a deep N-type well 112 may be formed under an N-type well-P-type well-N-type well structure around one of the P-type wells 176 to form a CMOS circuit, and a doping region having a type different from that of the deep N-type well 112, e.g., a P-type doping region 114, may be formed under the deep N-type well 112 to prevent a driving voltage Vdd from being applied to the N-type intermediate layer 124. The P-type doping region 114 may be referred to as a counter deep N-type well. Here, in the CMOS circuit formed of the N-type well-P-type well-N-type well structure on the deep N-type well 112, a negative (−) voltage may be applied to the P-type well 176 in the middle of the N-type well-P-type well-N-type well structure and thus the P-type well 176 may be an isolated pocket P-type well.

In the wiring layer 140, first through fourth interlayer insulating layers 141, 143, 145, and 147 and first through third metal wirings 142, 144, and 146 may be formed. The first through third metal wirings 142, 144, and 146 may be formed outside light transmission paths. Meanwhile, a ground electrode 142a for applying a ground bias voltage may be formed on the P-type well 172.

Although not illustrated in FIG. 1, the P-type upper layer 126 and the wiring layer 140 may include transistors for reading signals, e.g., a transfer transistor, a select transistor, a drive transistor, and a reset transistor, in the pixel region A. Also, the P-type upper layer 126 and the wiring layer 140 may include a plurality of transistors, gate lines, and source lines for forming CMOS circuits for processing signals, in the peripheral circuit region B. In FIG. 1, a reference numeral 141a may represent an insulating layer, such as a gate insulating layer.

The filter layer 150 is formed on the wiring layer 140 in the pixel region A, and includes a plurality of filters 152 corresponding to the photodiodes 130 formed below the filter layer 150. For example, red (R), yellow (Ye), and white (W) filters may be formed to correspond to the visible light photodiodes 130a and IR filters may be formed to correspond to the IR photodiodes 130b. Meanwhile, a protective layer 182 and a planarization layer 184 may be formed on the wiring layer 140 in the peripheral circuit region B.

The lenses 160 may be formed on the filter layer 150 to correspond to the filters 152. The lenses 160 focus light on the photodiodes 130.

As described above, in the CIS according to the current embodiment, a PNP triple layer may be formed on a substrate, an N-type intermediate layer in the PNP triple layer may prevent movement of electrons generated by IR light from a lower side of the N-type intermediate layer to a photodiode of a neighboring pixel, and thus crosstalk may be effectively prevented.

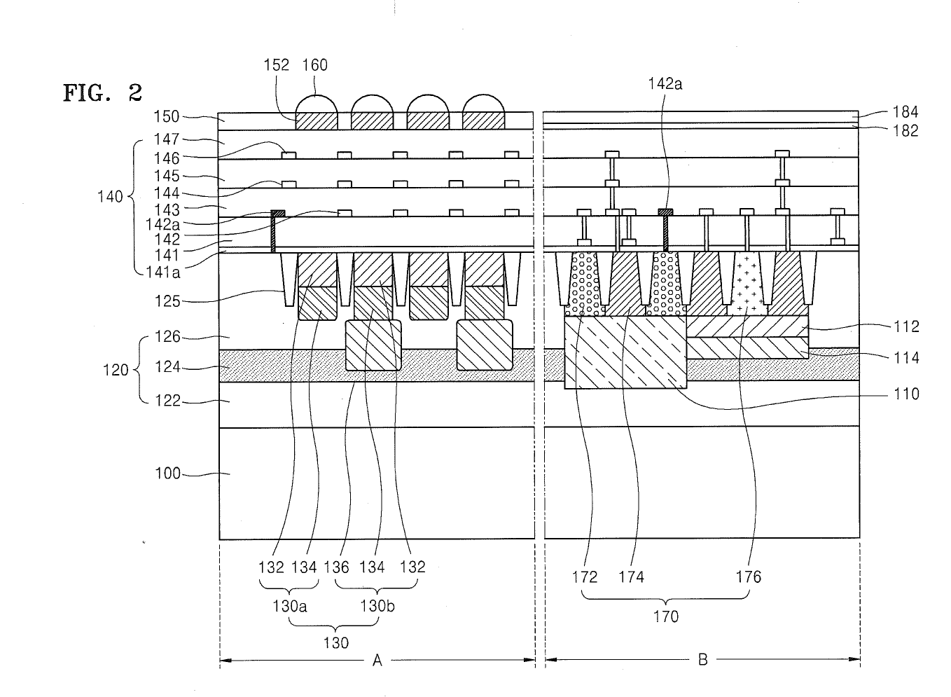

FIG. 2 is a cross-sectional view of a CIS including the PNP triple layer 120, according to another example embodiment. For convenience of explanation, only differences from the CIS illustrated in FIG. 1 will be described and repeated descriptions will not be provided here.

Referring to FIG. 2, like the CIS illustrated in FIG. 1, the CIS according to the current embodiment the substrate 100, the PNP triple layer 120, the photodiodes 130, the wiring layer 140, the filter layer 150, and the lenses 160. However, the IR photodiodes 130b of the photodiodes 130 are slightly different from those illustrated in FIG. 1.

That is, in the current embodiment, a deep NPD region 136b of the IR photodiodes 130b extends to the N-type intermediate layer 124 instead of extending to the P-type lower layer 122 through the N-type intermediate layer 124. Although the IR photodiodes 130b are formed as described above, minority carriers generated from the substrate 100 or the P-type lower layer 122 under the N-type intermediate layer 124 and diffused toward a neighboring pixel may flow to a corresponding IR photodiode 130b via the N-type intermediate layer 124, and thus crosstalk may be effectively suppressed.

Ultimately, in the CIS according to the current embodiment, after the PNP triple layer 120 is formed on the substrate 100, the deep NPD region 136b for forming the IR photodiodes 130b may be formed flexibly to a certain degree. For example, if the deep NPD region 136 is formed to overlap at least a portion of the N-type intermediate layer 124, crosstalk may be prevented due to a drain effect of the N-type inter mediate layer 124. However, for rapid flow of carriers from a lower side of the N-type intermediate layer 124 to the IR photodiodes 130b, the deep NPD region 136 may also extend to the P-type lower layer 122 as illustrated in FIG. 1.

Here, as in FIG. 1, a ground bias voltage is applied to the substrate 100, the P-type lower layer 122 and the P-type upper layer 126, and the N-type intermediate layer 124 is maintained in a floating state. Meanwhile, the ground bias voltage may be applied to the heavily-doped P-type (p++) substrate 100 via the deep P-type well 110 formed in the peripheral circuit region B. That is, if the ground bias voltage is applied to the ground electrode 142a which contacts one of the P-type wells 172 formed on the deep P-type well 110, the ground bias voltage may be applied to the substrate 100 via the P-type well 172 and the deep P-type well 110.

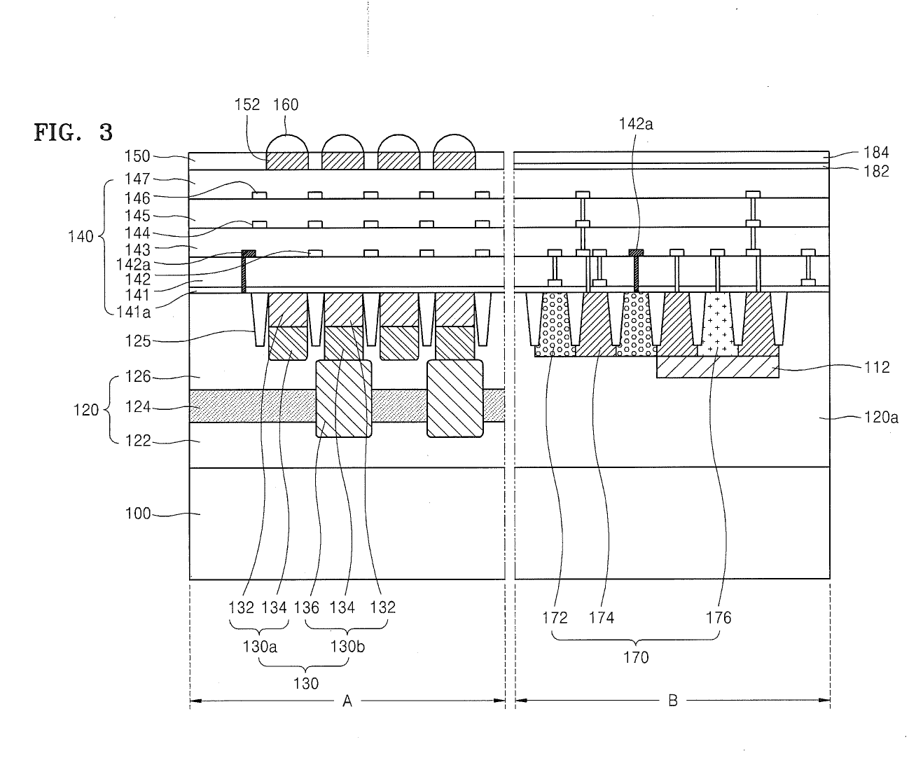

FIG. 3 is a cross-sectional view of a CIS including the PNP triple layer 120, according to another example embodiment. For convenience of explanation, only differences from the CIS illustrated in FIG. 1 will be described and repeated descriptions will not be provided here.

Referring to FIG. 3, like the CIS illustrated in FIG. 1, the CIS according to the current embodiment the substrate 100, the PNP triple layer 120, the photodiodes 130, the wiring layer 140, the filter layer 150, and the lenses 160. However, the PNP triple layer 120 is formed only in the pixel region A and not in the peripheral circuit region B.

The PNP triple layer 120 described above may be formed by forming a thick epitaxial layer on the substrate 100, forming the N-type intermediate layer 124 in the middle of the epitaxial layer by using a doping method, and blocking ions from being doped in the peripheral circuit region B by using a blank mask. As such, a P-type monolayer 120a may be formed on the substrate 100 in the peripheral circuit region B.

In the current embodiment, since the N-type intermediate layer 124 is not formed in the peripheral circuit region B, a deep P-type well is not required. That is, since the P-type monolayer 120a and the substrate 100 have the same doping type, a ground bias voltage may be directly applied to the substrate 100 by applying the ground bias voltage to one of the P-type wells 172 for forming a CMOS circuit.

Also, in the current embodiment, a driving voltage is prevented from being applied to the N-type intermediate layer 124 in the peripheral circuit region B, and a counter N-type well such as a P-type doping region is not required under the deep N-type well 112.

Furthermore, in the CIS according to the current embodiment, since the peripheral circuit region B is maintained in a conventional structure, processes in the peripheral circuit region B may not be changed and thus electrical characteristics of the peripheral circuit region B may be maintained the same.

FIG. 4 is a schematic view for describing operation of the CIS illustrated in FIG. 1, according to an example embodiment.

Referring to FIG. 4, light incident on the CIS is focused by the lenses 160. Then, only light of wavelengths corresponding to filters 152 is passed and light of other wavelengths is blocked by the filters 152. For example, IR filters 152a corresponding to the IR photodiodes 130b transmit light of IR wavelengths and block light of other wavelengths. IR light passed through the IR filters 152a is incident on the IR photodiodes 130b through the wiring layer 140. Meanwhile, IR light may permeate through the IR photodiodes 130b to a deep place, such as the P-type lower layer 122 and the substrate 100. As such, electron-hole pairs may be generated in the P-type lower layer 122 and the substrate 100.

In FIG. 4, dashed line arrows represent transmission paths of IR light and generated electrons (e⁻) and holes (h⁺) are illustrated. From among the generated carriers, the electrons flow to the IR photodiodes 130b due to a voltage difference and the holes flow to the ground electrode 142a through the deep P-type well 110 and one of the P-type wells 172 as described above in relation to FIG. 1. Moving paths of the electrons and holes are represented by solid line arrows.

Meanwhile, the electrons may be diffused toward a neighboring pixel as described above in relation to FIG. 1. However, the diffused electrons are drained by the N-type intermediate layer 124 and flow to the IR photodiode 130b of a corresponding pixel through the deep NPD region 136, which contacts the N-type intermediate layer 124, and thus crosstalk may be prevented.

In the CISs according to the above example embodiments, in addition to an effect of effectively preventing crosstalk due to a PNP triple layer, uniform photo response characteristics may be obtained due to an N-type intermediate layer uniformly formed over an entire pixel region, and ions may not be additionally injected or well taps may not be formed due to a constantly maintained floating state.

Furthermore, in a peripheral circuit region, the N-type intermediate layer may not function by forming a deep P-type well or may not be formed. As such, problems of a parasitic cap and a junction leakage current in an N-type substrate/P-type epitaxial layer structure may be prevented. Besides, since consecutive layers of the PNP triple layer have different doping types and thus are identified from each other, the thickness or resistivity of each layer may be easily monitored and thus may be easily managed.

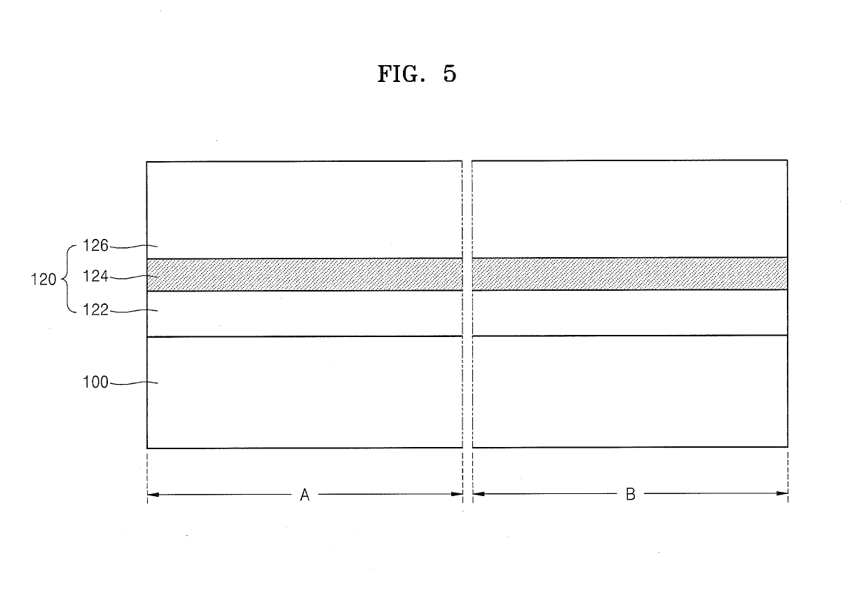

FIGS. 5 through 10 are cross-sectional views for describing a method of fabricating the CIS illustrated in FIG. 1, according to an example embodiment.

Referring to FIG. 5, the PNP triple layer 120 is formed on the substrate 100. The substrate 100 may be a heavily-doped P-type (P++) substrate and may be formed by using an epitaxial wafer. The heavily-doped P-type (P++) substrate may be formed by growing an epitaxial layer originally containing a heavily-doped of P-type ions such as boron (B) ions or by injecting P-type ions into an epitaxial wafer such that the substrate becomes heavily-doped.

The substrate 100 may be divided into the pixel region A in which the photodiodes 130 are formed, and the peripheral circuit region B for processing signals. The PNP triple layer 120 may be formed in both the pixel region A and the peripheral circuit region B.

Meanwhile, if an ion implantation method is used, the substrate 100 is not limited to an epitaxial wafer and any of various wafers such as a polished wafer, an annealed wafer, and an SOI wafer may also be used as the substrate 100.

The PNP triple layer 120 includes the P-type lower layer 122, the N-type intermediate layer 124, and the P-type upper layer 126, and may be formed by sequentially growing corresponding doping-type epitaxial layers on the substrate 100. For example, the P-type lower layer 122 may be formed by growing a P-type epitaxial layer having a relatively high resistivity of about 10 to 500 ohm·cm to a thickness of about 1 to 5 μm. The N-type intermediate layer 124 may be formed by growing an N-type epitaxial layer having a relatively high resistivity of about 10 to 500 ohm·cm to a thickness of about 1 to 5 μm. The P-type upper layer 126 may be formed by growing a P-type epitaxial layer having a relatively high resistivity of about 10 to 500 ohm·cm to a thickness of about 1 to 5 μm. Meanwhile, since photodiodes, N-type wells, and P-type wells are fog Hied in the P-type upper layer 126, the P-type upper layer 126 may be formed to have a thickness greater than either of those of the P-type lower layer 122 and the N-type intermediate layer 124.

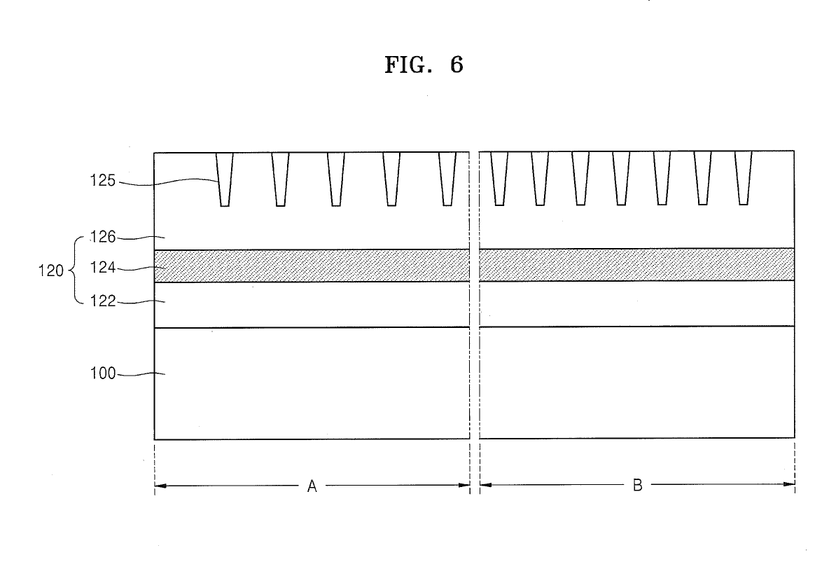

Referring to FIG. 6, the isolation regions 125, such as STIs, for isolating elements from each other are formed in the P-type upper layer 126. The isolation regions 125 may be formed in both the pixel region A and the peripheral circuit region B.

Meanwhile, in order to prevent crosstalk in the pixel region A, the isolation regions 125 may be formed more deeply in the pixel region A than in the peripheral circuit region B.

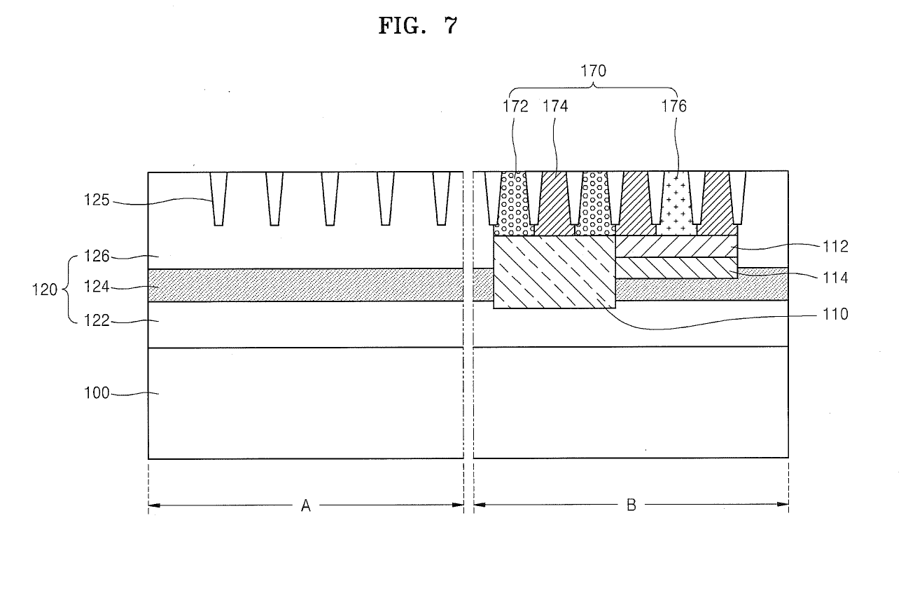

Referring to FIG. 7, the plurality of P-type wells 172 and N-type wells 174 for forming CMOS circuits are formed in the peripheral circuit region B. Also, in order to apply a ground bias voltage to the substrate 100, the deep P-type well 110 may be formed under a P-type well-N-type well-P-type well structure for forming a CMOS circuit. Meanwhile, the deep N-type well 112 may be formed under an N-type well-P-type well-N-type well structure for forming a CMOS circuit, and the P-type doping region 114 may be formed under the deep N-type well 112 to prevent a driving voltage from being applied to the N-type intermediate layer 124.

The deep P-type well 110, the deep N-type well 112, and the P-type doping region 114 may be formed after the P-type wells 172 and the N-type wells 174 are formed, or may be formed before the P-type wells 172 and the N-type wells 174 are formed, in consideration of sizes of doping regions, doping concentrations, etc. Meanwhile, in the CMOS circuit formed of the N-type well-P-type well-N-type well structure on the deep well N-type well 112, a negative (−) voltage may be applied to the P-type well 176 in the middle of the N-type well-P-type well-N-type well structure and thus the P-type well 176 may be an isolated pocket P-type well.

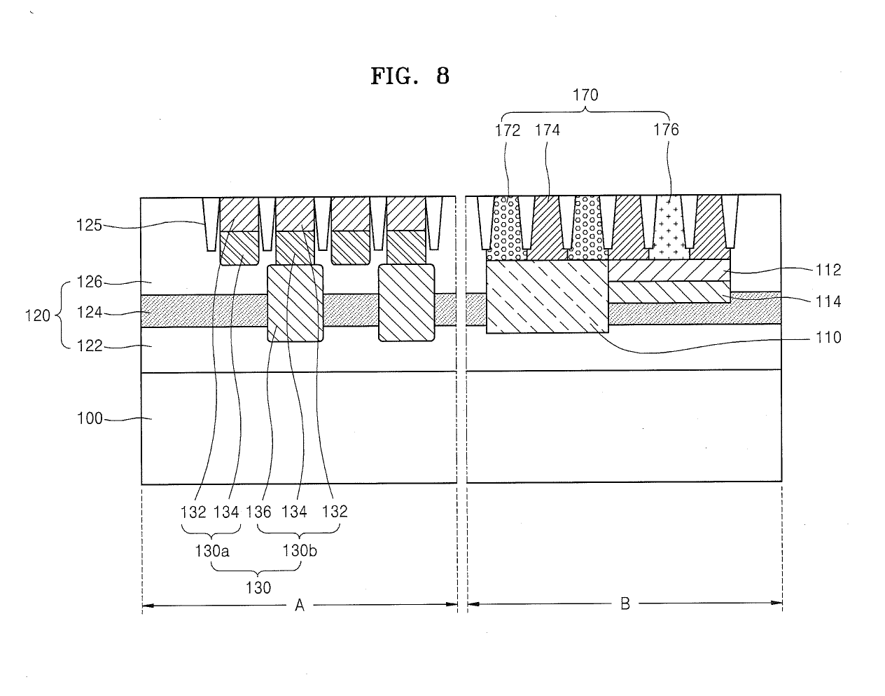

Referring to FIG. 8, the photodiodes 130 are formed in the pixel region A. The photodiodes 130 may include the visible light photodiodes 130a for sensing visible light and the IR photodiodes 130b for sensing IR light. The numbers and a pixel structure of the visible light photodiodes 130a and the IR photodiodes 130b may be appropriately changed according to required specifications of the CIS.

For example, the pixel region A may include four pixels. For example, three visible light photodiodes 130a and one IR photodiode 130b may be formed. In this case, the three visible light photodiodes 130a may use red (R), green (G), and blue (B) filters or may use yellow (Ye), red (R), and white (W) filters. However, the pixel structure and the filters are not limited thereto and may be variously changed.

As described above in relation to FIG. 1, each of the photodiodes 130 may be formed by forming the PPD region 132, i.e., a P-type impurity region, and the NPD region 134, i.e., an N-type impurity region, in the P-type upper layer 126. Meanwhile, each of the IR photodiodes 130b may further include the deep NPD region 136 under the NPD region 134. The deep NPD region 136 may extend from the P-type upper layer 126 to the P-type lower layer 122 through the N-type intermediate layer 124. However, in some cases, the deep NPD region 136 may extend to the N-type intermediate layer 124.

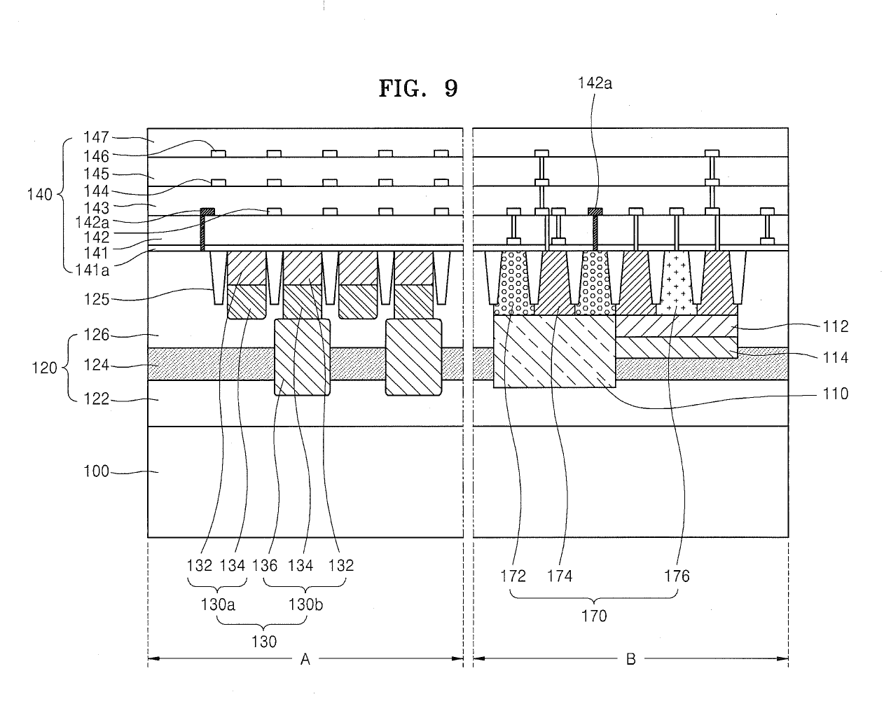

Referring to FIG. 9, the wiring layer 140 is formed in the pixel region A, in which the photodiodes 130 are formed, and in the peripheral circuit region B, in which the P-type wells 172 and the N-type wells 174 are fog med. The wiring layer 140 may include the first through fourth interlayer insulating layers 141, 143, 145, and 147 and the first through third metal wirings 142, 144, and 146 formed between the first through fourth interlayer insulating layers 141, 143, 145, and 147.

The first metal wiring 142 may include the ground electrodes 142a for applying a ground bias voltage to the P-type upper layer 126 and one of the P-type wells 172. In FIG. 9, the ground electrodes 142a are shaded. The positions of the ground electrodes 142a are not limited to as illustrated in FIG. 9 and may be variously changed to apply a ground bias voltage to the substrate 100, the P-type upper layer 126, and the P-type monolayer 120a.

Meanwhile, the first through third metal wirings 142, 144, and 146 formed in the pixel region A may be formed outside light transmission paths so that light is easily transmitted. For example, the first through third metal wirings 142, 144, and 146 may be formed above the isolation regions 125 formed in the pixel region A.

Although not illustrated in FIG. 9, the P-type upper layer 126 and the wiring layer 140 may include transistors for reading signals, e.g., a transfer transistor, a select transistor, a drive transistor, and a reset transistor, in the pixel region A. Also, the P-type upper layer 126 and the wiring layer 140 may include a plurality of transistors, gate lines, and source lines for forming CMOS circuits for processing signals, in the peripheral circuit region B.

Meanwhile, although the wiring layer 140 includes four interlayer insulating layers and three metal wirings in FIG. 9, the numbers of interlayer insulating layers and metal wirings are not limited thereto and may be increased or reduced in some cases.

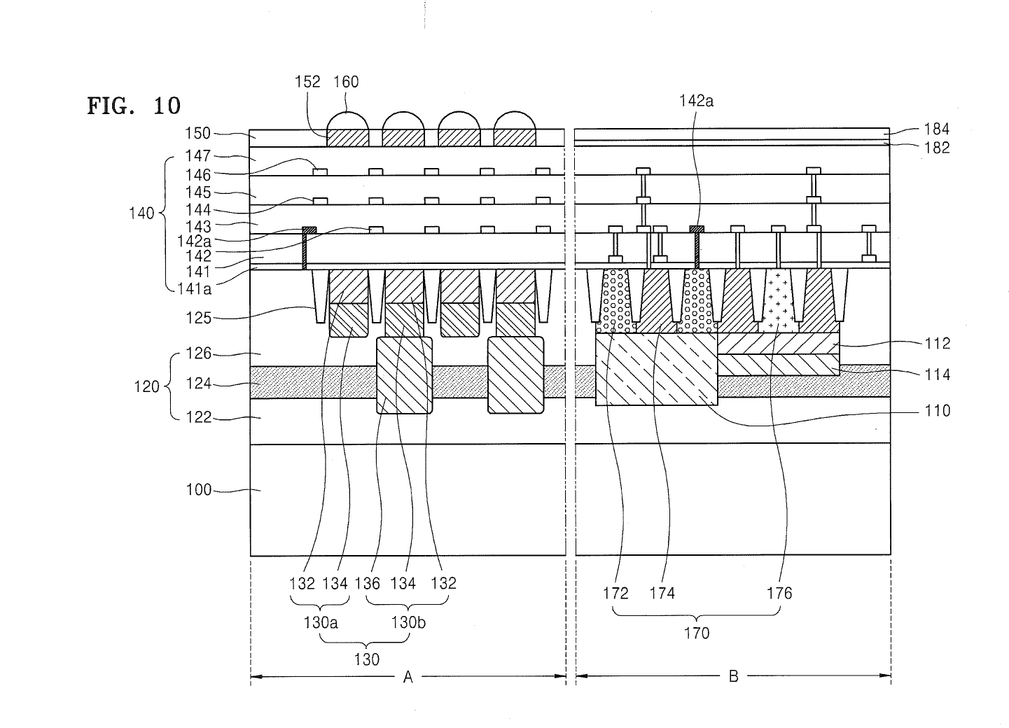

Referring to FIG. 10, the filter layer 150 and the lenses 160 are formed on the wiring layer 140 in the pixel region A. Also, the protective layer 182 and the planarization layer 184 are formed on the wiring layer 140 in the peripheral circuit region B.

The filter layer 150 may include the filters 152 corresponding to the photodiodes 130. For example, red (R), green (G), and blue (B) filters may be formed to correspond to the visible light photodiodes 130a and IR filters may be formed to correspond to the IR photodiodes 130b.

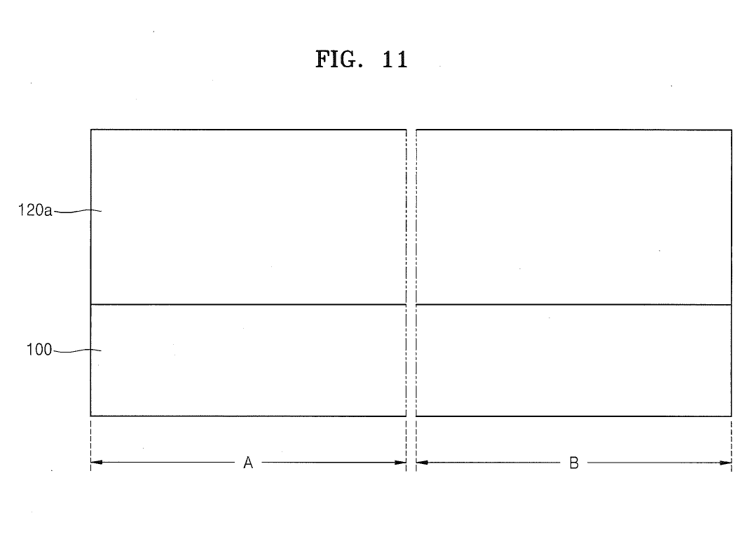

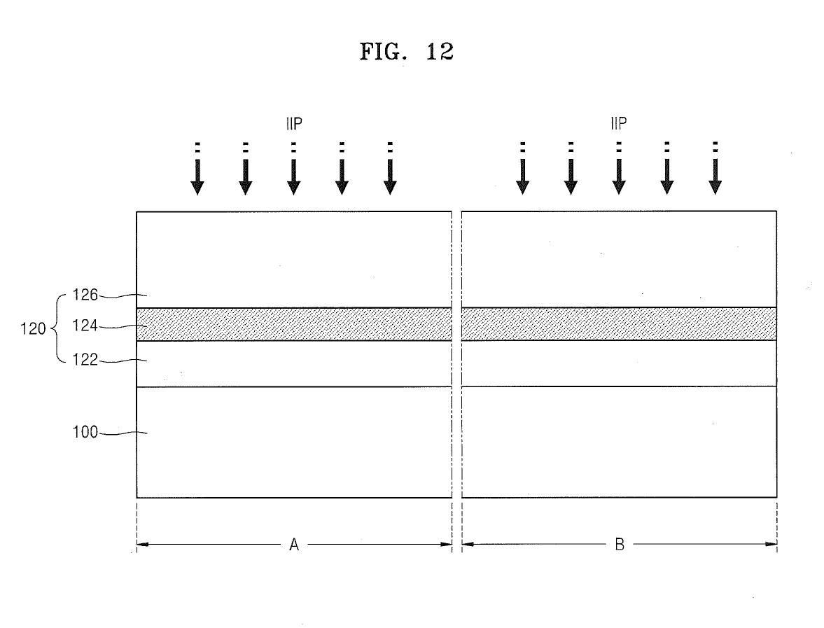

FIGS. 11 and 12 are cross-sectional views for describing a process of forming the PNP triple layer 120 of the CIS illustrated in FIG. 1, according to another example embodiment. The process illustrated in FIGS. 11 and 12 may be an alternative to the process illustrated in FIG. 5.

Referring to FIG. 11, the P-type monolayer 120a is formed on the substrate 100 to have a large thickness. The P-type monolayer 120a may be formed by growing a P-type epitaxial layer. The P-type monolayer 120a may have a large thickness corresponding to the thickness of the entire PNP triple layer 120 illustrated in FIG. 5.

Referring to FIG. 12, N-type ions such as phosphorus (P) ions are doped in the middle of the P-type monolayer 120a to form the N-type intermediate layer 124. The P-type lower layer 122 and the P-type upper layer 126 may be formed due to the N-type intermediate layer 124. That is, the PNP triple layer 120 may be formed by forming the N-type intermediate layer 124.

In the current embodiment, the N-type intermediate layer 124 may be formed over the entire P-type monolayer 120a. That is, the N-type intermediate layer 124 may also be formed in the peripheral circuit region B.

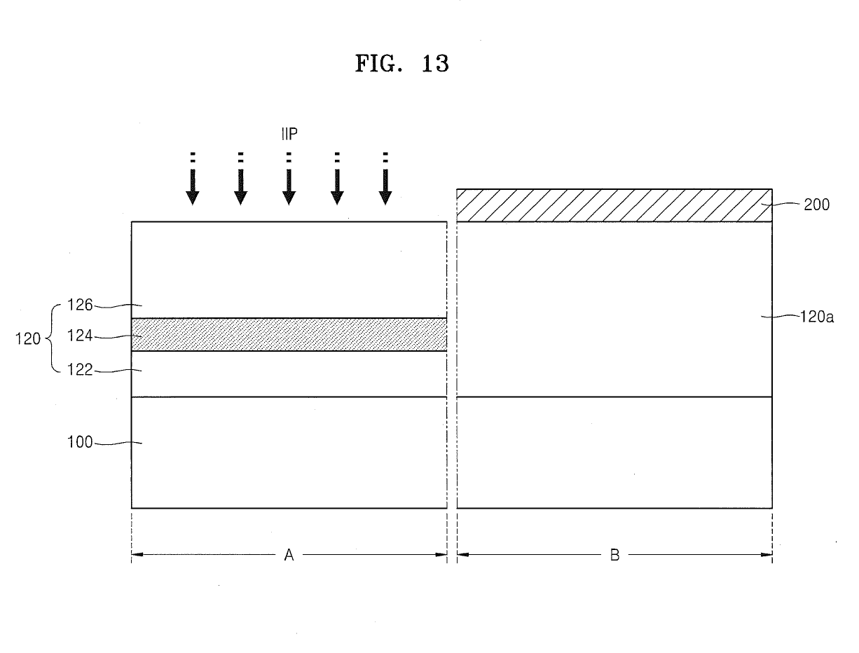

FIG. 13 is a cross-sectional view for describing a process of forming the PNP triple layer 120 of the CIS illustrated in FIG. 1, according to another example embodiment. In FIG. 13, the doping region illustrated in FIG. 12 is slightly modified.

Referring to FIG. 13, the P-type monolayer 120a is formed on the substrate 100 and then ion implantation is performed to form the N-type intermediate layer 124. However, unlike the process illustrated in FIG. 12, ion implantation may be performed on the P-type monolayer 120a in only the pixel region A instead of the entire P-type monolayer 120a. In more detail, a blank mask 200 is disposed on the peripheral circuit region B so that ion implantation is not performed on the P-type monolayer 120a in the peripheral circuit region B. As such, in the peripheral circuit region B, the N-type intermediate layer 124 is not formed and the P-type monolayer 120a is maintained.

The ultimate structure of the CIS fabricated by using the—method described above with reference to FIG. 13 is as illustrated in FIG. 3. That is, in FIG. 7, the deep P-type well 110 and the P-type doping region 114 may not be formed.

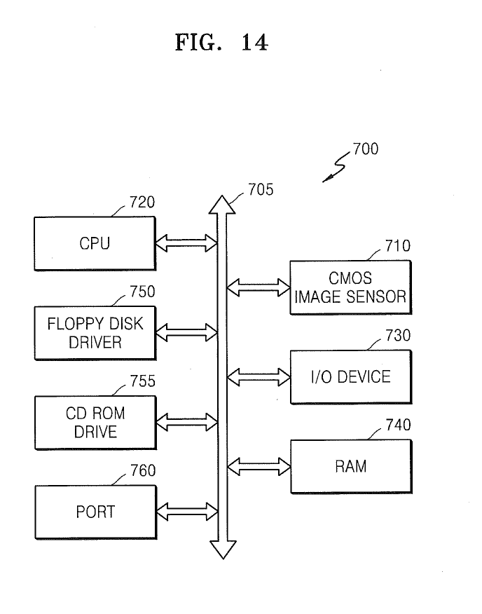

FIG. 14 is a block diagram of an electric and electronic system 700 including a CIS 710, according to an example embodiment.

Referring to FIG. 14, the electric and electronic system 700 processes an image output from the CIS 710. The electric and electronic system 700 may be any system including the CIS 710, e.g., a computer system, a camera system, a scanner, or an image safety system.

The electric and electronic system 700 based on a processor, e.g., a computer system, includes a central processing unit (CPU) 720, e.g., a microprocessor, for communicating with an input/output (I/O) device 730 via a bus 705. As the CPU 720 is connected to a floppy disk drive 750 and/or a compact disk (CD) read only memory (ROM) drive 755, a port 760, and random access memory (RAM) 740 via the bus 705 to exchange data, the image output from the CIS 710 may be reproduced.

The port 760 may be used to connect a video card, a sound card, a memory card, or a universal serial bus (USB) device, or may be used to exchange data with another system.

The CIS 710 may be integrated with the CPU 720, a digital signal processor (DSP), a microprocessor, or memory. In some cases, the CIS 710 may be separated from a processor.

The electric and electronic system 700 may be a camera phone or a digital camera from among recently developing digital devices, and the CIS 710 may be one of the CISs illustrated in FIGS. 1 through 3.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A CMOS image sensor (CIS) including a PNP triple layer, the CIS comprising:
a substrate;
the PNP triple layer including a P-type lower layer, an N-type intermediate layer, and a P-type upper layer that are sequentially stacked on the substrate;
a plurality of photodiodes formed in the P-type upper layer and isolated from each other by isolation regions;
a wiring layer formed on the P-type upper layer and the plurality of photodiodes, the wiring layer including a plurality of wirings; and
a plurality of lenses configured to transfer the light to the photodiodes.

2. The CIS of claim 1, wherein
the substrate is a heavily-doped P-type substrate, and
the P-type lower layer, the N-type intermediate layer, and the P-type upper layer are epitaxial layers.

3. The CIS of claim 1, wherein
the substrate is a heavily-doped P-type substrate, and
the P-type lower layer and the P-type upper layer are epitaxial layers, and the N-type intermediate layer is an implantation layer.

4. The CIS of claim 3, wherein
the substrate is divided into a pixel region and a peripheral circuit region, and
the N-type intermediate layer is formed in both the pixel region and the peripheral circuit region, or in only the pixel region.

5. The CIS of claim 1, wherein the plurality of photodiodes comprise visible light photodiodes configured to sense visible light and infrared (IR) photodiodes configured to sense IR light.

6. The CIS of claim 5, wherein
each of the plurality of photodiodes includes a lower N-type photodiode (NPD) region and an upper P-type photodiode (PPD) region, and
each of the IR photodiodes further includes a deep NPD region under the lower NPD region.

7. The CIS of claim 6, wherein the deep NPD region extends from the P-type upper layer to the N-type intermediate layer or extends from the P-type upper layer to the P-type lower layer through the N-type intermediate layer.

8. The CIS of claim 5, further comprising:
color filters under the lenses corresponding to the visible light photodiodes, and
IR filters under the lenses corresponding to the IR photodiodes.

9. A CMOS image sensor (CIS) including a PNP triple layer, the CIS comprising:
a substrate including a pixel region and a peripheral circuit region;
the PNP triple layer including a P-type lower layer, an N-type intermediate layer, and a P-type upper layer that are sequentially stacked on the substrate in the pixel region;
a plurality of photodiodes formed in the P-type upper layer in the pixel region and isolated from each other by isolation regions;
a wiring layer formed on the P-type upper layer and the photodiodes and including a plurality of wirings; and
a plurality of lenses configured to transfer the light to the photodiodes.

10. The CIS of claim 9, wherein
the substrate is a heavily-doped P-type substrate, and
the P-type lower layer, the N-type intermediate layer, and the P-type upper layer are epitaxial layers.

11. The CIS of claim 9, wherein
the substrate is a heavily-doped P-type substrate, and
the P-type lower layer and the P-type upper layer are epitaxial layers, and the N-type intermediate layer is an implantation layer.

12. The CIS of claim 9, wherein
the PNP triple layer is formed in the peripheral circuit region,
a plurality of P-type wells and N-type wells for forming CMOS circuits are alternately formed in the P-type upper layer in the peripheral circuit region,
a deep P-type well is formed under a P-type well-N-type well-P-type well structure, and a deep N-type well is formed under an N-type well-P-type well-N-type well structure, and
the deep P-type well contacts the P-type wells of the P-type well-N-type well-P-type well structure, and extends from the P-type upper layer to the P-type lower layer through the N-type intermediate layer.

13. The CIS of claim 12, wherein
the substrate is a heavily-doped P-type substrate.

14. The CIS of claim 12, wherein a P-type doping region is formed under the deep N-type well.

15. The CIS of claim 9, wherein
a P-type monolayer is formed on the substrate in the peripheral circuit region,
a plurality of P-type wells and N-type wells for forming CMOS circuits are alternately formed in the P-type monolayer, and
a deep N-type well is formed under an N-type well-P-type well-N-type well structure.

16. The CIS of claim 15, wherein
the substrate is a heavily-doped P-type substrate.

17. The CIS of claim 9, wherein
the photodiodes comprise visible light photodiodes configured to sense visible light and infrared (IR) photodiodes configured to sense IR light,
each of the photodiodes includes a lower N-type photodiode (NPD) region and an upper P-type photodiode (PPD) region, and
each of the IR photodiodes further includes a deep NPD region under the lower NPD region.

18. The CIS of claim 17, wherein the deep NPD region extends from the P-type upper layer to the N-type intermediate layer or extends from the P-type upper layer to the P-type lower layer through the N-type intermediate layer.

19. A CMOS image sensor (CIS) including a PNP triple layer, the CIS comprising:
a substrate including a pixel region;
the PNP triple layer including a P-type lower layer, an N-type intermediate layer, and a P-type upper layer that are sequentially stacked on the substrate;
a plurality of photodiodes formed in the P-type upper layer and isolated from each other by isolation regions, the plurality of photodiodes including a first type of photodiode formed such that the first type of photodiode extends at least from an upper surface of the P-type upper layer to an upper surface of the N-type intermediate layer.

20. The CIS of claim 19 further comprising:
a wiring layer formed on the P-type upper layer and the plurality of photodiodes, the wiring layer including a plurality of wirings; and
a plurality of lenses configured to transfer the light to the photodiodes.

21. The CIS of claim 20, wherein the substrate further includes a peripheral circuit region, and
the P-type lower layer, N-type intermediate layer, and P-type upper layer of the PNP triple layer are sequentially stacked on the substrate in the pixel region.
